(19) United States
(12) Patent Application Publication
(10) Pub. No.: US 2016/0358654 A1
(43) Pub. Date: Dec. 8, 2016

(54) LOW-POWER TERNARY CONTENT ADDRESSABLE MEMORY

(71) Applicant: Cisco Technology, Inc., San Jose, CA (US)

(72) Inventor: John HOLST, Saratoga, CA (US)

(21) Appl. No.: 15/043,323

(22) Filed: Feb. 12, 2016

Related U.S. Application Data
(60) Provisional application No. 62/169,848, filed on Jun. 2, 2015.

(51) Int. Cl. G11C 15/04

(52) U.S. Cl. CPC G11C 15/04

(57) ABSTRACT

Aspects of the present disclosure generally relate to computer memory, and more specifically, to a low-power content addressable memory (CAM) circuit and a method of operating the CAM. According to certain aspects, techniques described herein may function to reduce the number of intermediate match lines of the CAM that switch during a comparison operation, reduce the voltage swing on the intermediate output lines, and reduce a switched capacitance of the CAM.

### CLAIM FOR PRIORITY UNDER 35 U.S.C. §119

The present Application for Patent claims priority to U.S. Provisional Application No. 62/169,848 filed Jun. 2, 2015, and assigned to the assignee hereof and expressly incorporated herein by reference.

### TECHNICAL FIELD

Embodiments presented herein generally relate to computer memory, and more specifically, to a low-power ternary content addressable memory (TCAM) circuit.

### BACKGROUND

Content Addressable Memories (CAMS) are commonly used in cache and other address translation systems of high speed computing systems. Ternary Content Addressable Memories (TCAMs) use ternary state CAM cells and are commonly used for parallel search in high performance computing systems. The unit of data that is stored in a TCAM bitcell is ternary, having three possible states: logic one, logic zero, and don't care (X). To store these three states, TCAM bitcells include a pair of memory elements.

A TCAM system comprises TCAM blocks with arrays of TCAM bitcells. A TCAM system typically has a TCAM block array (M×N) that includes a plurality of rows (M) of TCAM bitcells and a plurality of columns (N) of TCAM bitcells. These arrays typically have vertically running bit lines and search lines for data read/write function and horizontal running word lines and match lines. TCAM bitcells in a column share the same bit lines and search lines, whereas the word lines and match lines are shared by cells in a row. Besides a pair of memory elements, each TCAM bitcell includes comparison circuitry.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a general block diagram of computing system with a ternary content addressable memory (TCAM), according to certain aspects of the present disclosure.

FIG. 2 illustrates an architecture of a TCAM device comprising an array of TCAM bitcells, according to certain aspects of the present disclosure.

FIG. 3 illustrates an example architecture of a TCAM bitcell, according to certain aspects of the present disclosure.

FIG. 4 illustrates an example TCAM with NOR-architecture comparison circuitry, according to certain aspects of the present disclosure.

FIG. 5 illustrates an example TCAM with NAND-architecture comparison circuitry, according to certain aspects of the present disclosure.

FIG. 6 illustrates an example circuit of a low-power TCAM with comparison circuitry using a single compound gate, according to certain aspects of the present disclosure.

FIG. 7 illustrates example operations for operating a TCAM bitcell, according to certain aspects of the present disclosure.

FIG. 8 illustrates an example architecture of a binary content addressable memory (BCAM), according to certain aspects of the present disclosure.

FIG. 9 illustrates example comparison circuitry for a BCAM, according to certain aspects of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DESCRIPTION OF EXAMPLE EMBODIMENTS

### Overview

Embodiments of the present disclosure provide a content addressable memory (CAM) bitcell. The CAM bitcell generally includes bit storage comprising one or more memory cells for holding stored data, bit comparison circuitry operative to compare the stored data and search data, received on a search line coupled to the CAM bitcell, and to provide a match output signal on an output match line. The bit comparison circuitry generally includes a plurality of stages, each stage comprising an input gate for receiving an input voltage and an output gate for providing an output voltage on an intermediate match line, wherein each stage is serially connected, directly or indirectly, between a power supply and the output match line, and wherein a voltage swing on each intermediate match line is configured to be less than a voltage swing on the output match line when a mismatch occurs during a comparison operation. Additionally, the CAM bitcell includes match circuitry coupled to receive the match output signal from the CAM bitcell for determining whether a match is present for a given search word.

Embodiments of the present disclosure provide a method for operating a content addressable memory (CAM) bitcell. The method may generally include receiving stored data from one or more memory cells of the CAM bitcell, receiving search data on a search line coupled to the CAM bitcell, performing, using bit comparison circuitry, a comparison operation to compare the stored data and the search data. The bit comparison circuitry generally includes a plurality of stages, each stage comprising an input gate for receiving an input voltage and an output gate for providing an output voltage on an intermediate match line, wherein each stage is serially connected, directly or indirectly, between a power supply and a output match line, and wherein a voltage swing on each intermediate match line is configured to be less than a voltage swing on the output match line when a mismatch occurs during a comparison operation. The method also generally includes determining, using match circuitry coupled to the CAM bitcell, a match is present for a given search word based on the comparison operation.

Embodiments of the present disclosure provide logic encoded in one or more tangible media for execution and when executed operable to receive stored data from one or more memory cells of a content addressable memory (CAM) bitcell, receive search data on a search line coupled to the CAM bitcell, perform, using bit comparison circuitry, a comparison operation to compare the stored data and the search data. The bit comparison circuitry generally includes a plurality of stages, each stage comprising an input gate for receiving an input voltage and an output gate for providing an output voltage on an intermediate match line, wherein each stage is serially connected, directly or indirectly, between a power supply and the output match line, and wherein a voltage swing on each intermediate match line is configured to be less than a voltage swing on the output match line when a mismatch occurs during a comparison operation. The logic is additionally operative to determine, using match circuitry coupled to the CAM bitcell, a match is present for a given search word based on the comparison operation.

### Example Embodiments

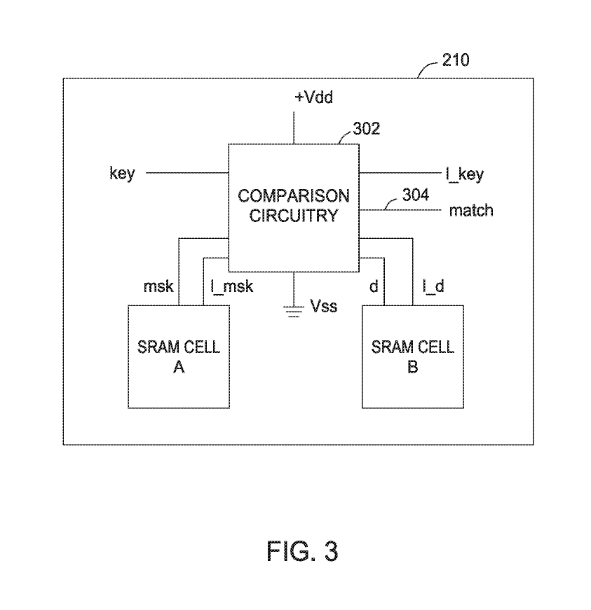

As noted above, a TCAM system comprises TCAM blocks with arrays of TCAM bitcells. A TCAM system typically has a TCAM block array (M×N) that includes a plurality of rows (M) of TCAM bitcells and a plurality of columns (N) of TCAM bitcells. These arrays typically have vertically running bit lines and search lines for data read/write function and horizontal running word lines and match lines. TCAM bitcells in a column share the same bit lines and search lines, whereas the word lines and match lines are shared by cells in a row. Besides a pair of memory elements, each TCAM bitcell includes compare circuitry, for example, as described in greater detail below with reference to FIG. 3.

Conventional TCAM bitcells are characterized by circuitry capable of generating a match output for each row of TCAM bitcells in the TCAM block array thereby indicating whether any location of the array contains a data pattern that matches a query input and the identity of that location. Each TCAM bitcell typically has the ability to store a unit of data, and the ability to compare that unit of data with a unit of query input and each TCAM block has the ability to generate a match output. In a conventional parallel data search, an input keyword is placed at the search bit lines after precharging the match lines to a power supply voltage Vdd. The data in each TCAM bitcell connected to a match line is compared with this data, and if there is a mismatch in any cell connected to a match line, the match line will discharge to ground through the comparison circuitry of that TCAM bitcell. A compare result indication of each TCAM block in a row is combined to produce a match signal for the row to indicate whether the row of TCAM bitcells contains a stored word matching a query input. The match signals from each row in the TCAM bitcell together constitute match output signals of the array; these signals may be encoded to generate the address of matched locations or used to select data from rows of additional memory.

TCAMs have been an emerging technology for applications including packet forwarding in the networking industry and are recognized as being fast and easy to use. However, due to their inherent parallel structure and precharging required for operation, they consume high power, much higher as compared to SRAMs or DRAMs. What is needed is a new lower power TCAM design that significantly reduces power dissipation.

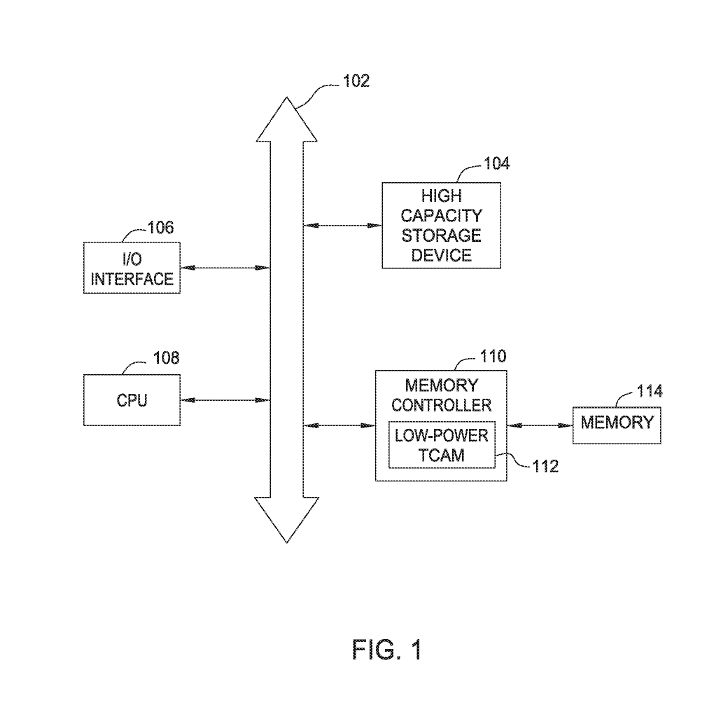

FIG. 1 illustrates an example of a computing system 100, according to certain embodiments of the present disclosure. The computing system 100 comprises a high capacity storage device 104, an input/output (I/O) interface 106, a central processing unit (108), a memory controller 110, and a main memory 114, which are connected with one another via a system bus 102. As illustrated, the memory controller 110 may include a ternary content addressable memory (TCAM) device 112. As will be described in greater detail below, the TCAM device 112 may include circuitry for decreasing power dissipation, in accordance with aspects of the present disclosure. While the TCAM device 112 is a ternary content addressable memory, the TCAM device 112 may comprise other types of content addressable memory, such as a binary content addressable memory (BCAM).

The high capacity storage device 104 may comprise a solid state drive (SSD), a hard disk drive (HDD), and/or a network-attached storage (NAS). The main memory 114 may comprise flash memory, phase-change RAM (PRAM), and/or magnetic RAM (MRAM).

The I/O interface 106 may comprise a keyboard, a mouse, a monitor display, and/or any other type of device that is capable of inputting or outputting information to/from the computing system 100. In some cases, the I/O interface 106 may be connected with a network port that can be connected to a network or may be directly connected with the network.

During operation of the computing system 100, the CPU 108 may control the operation of the memory controller 110 and the main memory 114. In some cases the memory controller 110 controls the main memory 114.

While the computing system 100 illustrates particular components, it should be understood that these components may be interchanged. For example, the CPU 108 may be any type of CPU and the main memory 114 may be any one of various types of memory. It should also be understood that the computing system 100 is not restricted to the embodiment illustrated in FIG. 1 and may further include other components.

The computing system 100 illustrated in FIG. 1 is just an example of a computing system including the TCAM device 112. The TCAM device 112 may be used in any computing systems requiring TCAM.

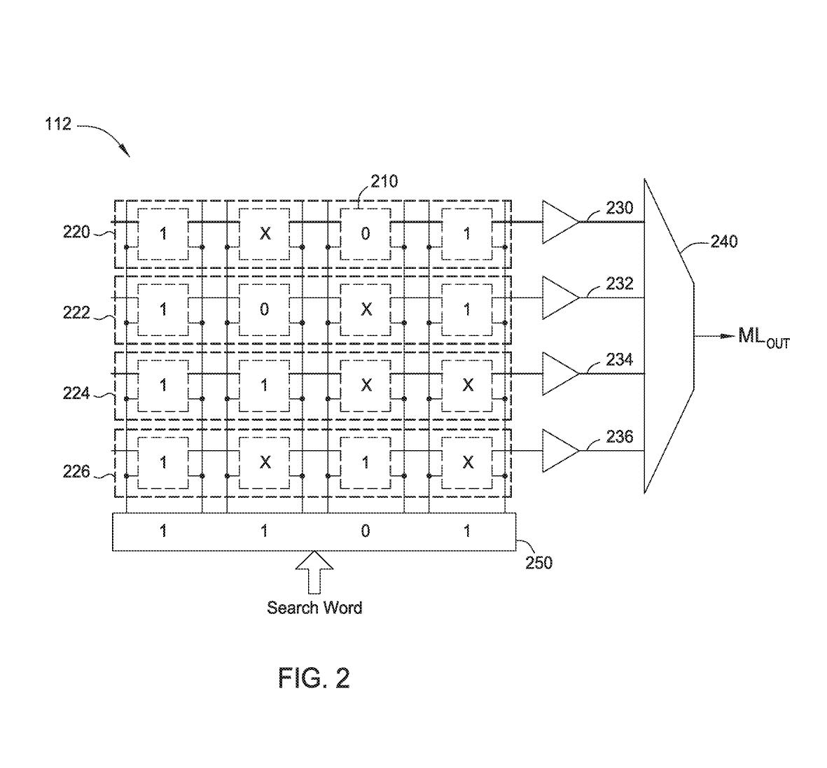

FIG. 2 illustrates an architecture of a TCAM device (e.g., TCAM 112) comprising an array of TCAM bitcells. As illustrated in FIG. 2, a search word, such as “1101,” may be input to a register 250 of the TCAM 112. The search word may be compared to the value stored in the TCAM bitcells 210. The search may be simultaneously conducted across the TCAM bitcells 210. The content of the TCAM bitcells 210 may be a high bit (1), a low bit (0), or a mask value (X). Prior to the search, a match line 230-236 for each set of TCAM cells 220-226 may be set to high. The match lines 230-236 are input to a priority encoder 240. The TCAM 112 outputs (MLout) the address of the set of TCAM cells that match the search word line. Because the search is a parallel search, the search may be completed in one clock cycle. It should be noted that a mask value may be a 0 or 1, still, in the present disclosure, the mask value may be referred to as an X.

As an example, as illustrated in FIG. 2, a first set of TCAM bitcells 220 is set to “1 X 0 1,” a second set of TCAM bitcells 222 is set to “1 0 X 1,” a third set of TCAM bitcells 224 is set to “1 1 X X,” and a fourth set of TCAM bitcells 226 is set to “1 X 1 X.” When comparing the content of the TCAM bitcells to the search bit, when the content of the TCAM cell is a mask value X, the comparison will yield a match. Thus, according to the example illustrated in FIG. 2, the first set of TCAM bitcells 220 and the third set of TCAM bitcells 224 match the search word in the register 250. Accordingly, the match lines 230 and 234 of the first set of TCAM bitcells 220 and the third set of TCAM bitcells 224 will indicate a match and the priority encoder 240 outputs the address of either the first set of TCAM bitcells 220 or the third set of TCAM bitcells 224 depending on which one has priority.

FIG. 3 illustrates an example architecture of a TCAM bitcell (e.g., TCAM bitcell 210), according to certain aspects of the present disclosure. The TCAM bitcell 210 may include two 6-transistor (6-T) static random access memory (SRAM) cells (e.g., SRAM cell A and B) that contain mask information (e.g., ‘msk’ signal) and stored data (e.g., signal ‘d’), respectively. The TCAM bitcell may also include comparison circuitry 302 operable to provide a match output signal (e.g., on output match line 304) during a comparison/search operation (e.g., as described above with reference to FIG. 2).

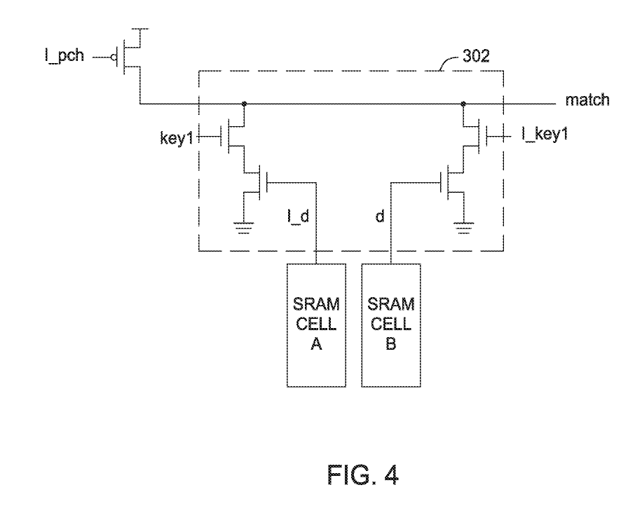

According to certain aspects, and as will be described in greater detail below (e.g., with reference to FIGS. 4, 5, and 6), the comparison circuitry 302 may comprise various logic gates for comparing the stored data (e.g., stored in SRAM B) with a search bit (e.g., provided by the ‘key’ signals in FIG. 3), for example, as described above.

As illustrated, comparison circuitry 302 comprises six inputs: data signals, ‘d’ and ‘I_d’, mask signals, ‘msk’ and ‘I_msk’, and key signals, ‘key’ and ‘I_key’. While FIG. 3 illustrates one example architecture of a TCAM bitcell, other TCAM bitcell architectures may exist.

According to certain aspects and with reference to FIG. 3, the ‘key’ and ‘I_key’ signals represent the values on the search lines, the ‘d’ and ‘I_d’ signal represents the data stored in SRAM B, and the ‘msk’ and ‘I_msk’ signals represents a mask bit stored in SRAM A. When the mask bit stored in SRAM A is set to logic 0, the bit stored in SRAM B is valid and may participate in a comparison operation. When mask bit stored in SRAM A is set to logic 1, the bit stored in SRAM B represents a “don't-care”, meaning during a comparison operation a match is generated regardless of the value of the bit stored in SRAM B.

As described above, each TCAM bitcell 210 has comparison circuitry 302 for bit comparison that can generate a compare result for the TCAM bitcell 210. In particular, a data value (e.g., signal ‘d’) stored in an SRAM cell (e.g., SRAM B) can be compared against search line data values (‘key’ and ‘I_key’) provided on the respective search lines. In the particular arrangement of FIG. 3, in the event of a match for the comparison, the match line 304 becomes logic HIGH. In the event of a mismatch compare result, the comparison circuitry 302 can provide a discharge path to a low power supply voltage, VSS, and thus the output match line 304 becomes LOW. For example, the comparison circuitry 302 may provide a logic HIGH output on output match line 304 when the a search bit (‘key’ and ‘I_key’) match the stored bits (‘d’ and ‘I_d’), or a mask bit in SRAM A is set to logic HIGH.

Generally, TCAM comparison circuitry (e.g., comparison circuitry 302) may be divided into two categories. A first category of TCAMs comprises TCAMs that use “NOR” architecture. “NOR” architecture TCAMs are most commonly implemented using dynamic logic, but can also be implemented using ratioed loads. The defining characteristic for the “NOR” architecture category of TCAMs is that the MATCH line from multiple bits are connected together to form a NOR-type of gate. In a typical dynamic implementation, the common MATCH node is pre-charged high. Both true and complement polarities of each search key bit are precharged low. Either the true or complement polarity of each search key bit then transitions high. Any bit in a TCAM entry (i.e., a row of TCAM cells in the TCAM block, having a common match line) that does not match the search key data imposed upon it will then discharge the common MATCH line for that entry. The majority of comparisons yield a mismatch, and therefore, the dynamic NOR has an increased power consumption as a result of switching from HIGH to LOW for indicating a mismatch. Furthermore, the dynamic NOR has a complex timing control because the pre-charge signal is used by each match line in each clock cycle.

FIG. 4 illustrates an example TCAM with NOR-architecture comparison circuitry. According to certain aspects, the comparison circuitry 302 illustrated in FIG. 3 may comprise the example NOR-architecture comparison circuitry illustrated in FIG. 4. In this implementation, the three states of the TCAM (e.g., 1, 0, and “don't-care”) are encoded into the pair of SRAM cells as [1,0], [0,1], and [0,0]. In all NOR architecture TCAM implementations, the MATCH nodes from multiple cells directly tied together, which may be referred to as a “wired-or” circuit configuration. While FIG. 4 shows one example of a NOR architecture TCAM other examples may exist.

TCAMs are normally used in a manner where only one (or a few) entry(s) in a memory array will match an incoming search key. For a NOR architecture TCAM design, this means that most of the TCAM entries will have their match lines pulled LOW, and later pre-charged back to the HIGH. This constant discharge/pre-charge activity is the root source of thermal and instantaneous power issues related to NOR architecture TCAMs, as noted above.

A second category of TCAM circuits comprises TCAMs that use a “NAND” architecture. A defining characteristic for NAND architecture TCAMs is that the MATCH function is computed with logic gates that use a series of stacked transistors rather than a set of parallel transistors, which may be referred to as “NAND style” gates. So that a pre-charge function is not required, NAND architecture TCAMs almost always use static CMOS NAND-style gates where the MATCH signal is typically generated by a series of NAND-style gates rather that one single gate with a large fan-in.

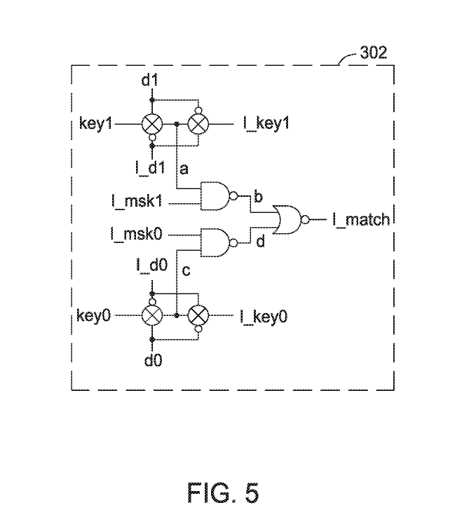

FIG. 5 illustrates an example TCAM with NAND architecture comparison circuitry. It should be noted that the comparison circuitry 302 illustrated in FIG. 3 may comprise the NAND architecture comparison circuitry illustrated in FIG. 5. According to certain aspects, the FIG. 5 depicts 2 bits in a TCAM entry. Each of the two bits shown in the circuit of FIG. 5 would have 2 memory cells attached to it that contain the data (e.g., the d and I_d signals) and mask (e.g., I_msk) information. For simplicity, these memory cell structures are not shown in FIG. 5.

NAND architecture TCAMs (i.e., TCAMs that use NAND architecture in their comparison circuitry) typically require more silicon area to construct, and are typically slower than their NOR architecture TCAM (i.e., TCAMs that use NOR architecture in their comparison circuitry) counterparts. In general operation, though, NAND architecture TCAMs dissipate significantly less power. The use of static, combinational gates results in fewer signals (and less overall switched capacitance) being switched during a typical compare/search operation. However, while NAND architecture TCAMs generally consume less power than NOR architecture TCAMs, NAND architecture TCAMs do have a use case in which they can generate significant thermal and instantaneous power requirements.

For example, this use case may occur when a user programs all (or a large number of) TCAM entries with identical data and all (or a large number) of the MASK bits are set low (i.e., there are no “don't care” bits), and then then imposes search key data that alternates cycle by cycle between matching all bit positions and matching no bit positions (or something approaching this behavior). This results in toggle activity for every net within the TCAM array during each cycle. For example, with reference to FIG. 5, this means that 5 nets (labeled a, b, c, d, and I_match) will switch between Vdd (e.g., HIGH) and Vss (e.g., LOW) power supplies during every cycle, generating significant thermal and instantaneous power requirements.

The majority of the power dissipation in a typical NAND architecture TCAM occurs in the logic gates depicted in FIG. 5, as these gates are replicated throughout the TCAM array. Thus, aspects of the present disclosure provide a TCAM for reducing power dissipation during a searching operation. For example, in order to reduce power dissipation associated with discrete logic gates, aspects of the present disclosure provide a TCAM that replaces the comparison circuitry illustrated in FIG. 5 (e.g., discrete NAND gates) with comparison circuitry that comprises a single compound logic gate.

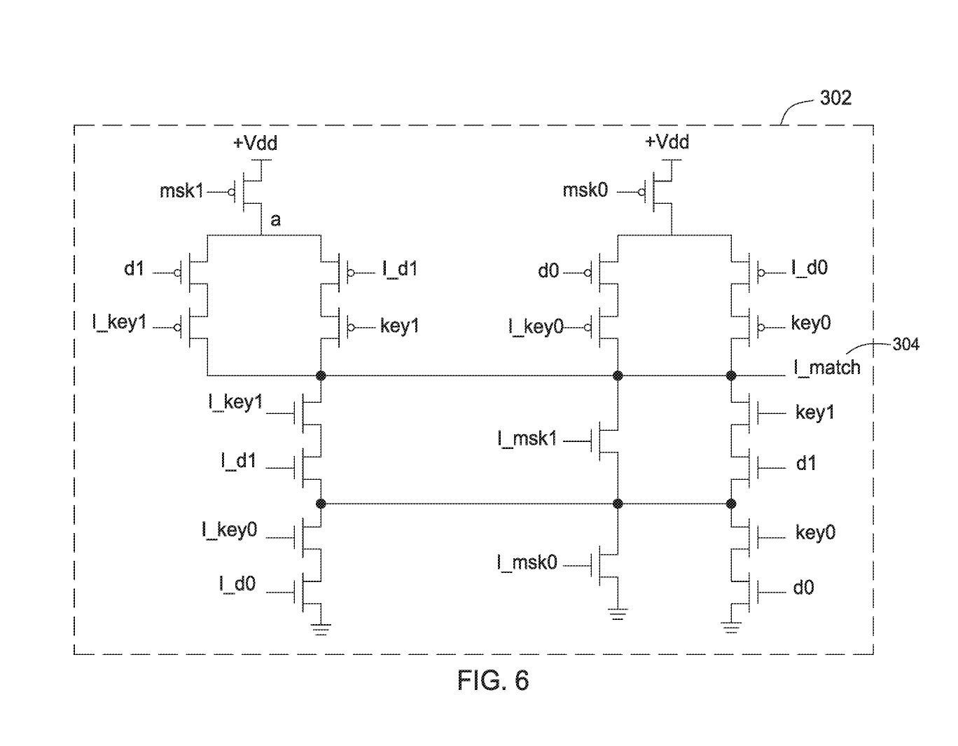

FIG. 6 illustrates an example circuit of a low-power TCAM with comparison circuitry using a single compound gate, according to certain aspects of the present disclosure. According to certain aspects, the comparison circuitry 302 illustrated in FIG. 3 may comprise the comparison circuitry (i.e., the compound gate) illustrated in FIG. 6.

According to certain aspects, the compound gate illustrated in FIG. 6 comprises 20 transistors, which may be identical to the transistor count of the five discrete logic gates of the NAND architecture TCAM illustrated in FIG. 5. Being a compound gate, however, may reduce the number of nets, or intermediate match lines, that switch rail-to-rail (e.g., Vdd to Vss/ground) from five to one, thus reducing the power dissipation. For example, as illustrated in FIG. 5, the NAND architecture TCAM comprises 5 nets (e.g., labeled a-d and I_match) that may switch from rail-to-rail while the compound gate TCAM illustrated in FIG. 6 only comprises a single net (e.g., labeled ‘I_match’) that can switch rail-to-rail, as explained in greater detail below.

For example, other than I_match (e.g., the output match line to the comparison circuitry 302 in FIG. 6), there are several other nets within the comparison circuitry 302 illustrated in FIG. 6. According to certain aspects, these additional nets, or “intermediate output lines”, may all be formed by the series connection of either NFET or PFET devices. As a result, the voltage swing of these intermediate output lines may be reduced by the threshold voltage of these FETs. For example, the intermediate output line labeled ‘a’ in FIG. 6 (e.g., net ‘a’) is connected to 3 P-FET devices whose threshold voltage (Vtp) is, for example, 300 mV, so intermediate match line ‘a’ is unable to be pulled all the way down to ground as it is isolated from ground by the two P-FET devices below it. Thus, the intermediate match line labeled ‘a’ may only swing between Vdd and 300 mv (i.e., the threshold voltage). This reduced switching voltage/voltage swing when reproduced for each net, except for the I_match net, in the comparison circuitry 302 illustrated in FIG. 6 helps reduce overall power dissipation of the TCAM device. For example, according to certain aspects, replacing the comparison circuitry comprised of five discrete logic gates illustrated in FIG. 5 with comparison circuitry comprising a single compound gate (e.g., comparison circuitry 302 illustrated in FIG. 6) may reduce the power dissipation by 45% in a 22 nm process as compared to TCAMs with discrete logic gates.

Additionally, according to certain aspects, power dissipation may also be reduced since the parasitic switched capacitance associated with the nets formed by the series connection of transistors illustrated in FIG. 6 is typically less than the output capacitance of a discrete logic gate.

Additionally, according to certain aspects, power dissipation may be reduced by assigning the input signals to the transistors illustrated in FIG. 6 in a particular order. For example, the input connections/signals to this compound gate of the comparison circuitry 302 in FIG. 6 may be assigned in a manner (e.g., in a particular order) that reduces the number of internal nets/intermediate match lines that switch, according to certain aspects of the present disclosure. For example, the msk, I_msk, d and I_d input pins are driven directly by the values stored in the local memory cells, and can only change state during write operations. As such, these signals do not switch during a search/compare operation. The key1, I_key1, key0, and I_key0 input signals, on the other hand, are driven by a search word and may switch during a comparison operation.

Thus, according to certain aspects, in order to reduce unnecessary voltage swings and thus reduce power dissipation in the TCAM, input signals that do not change during a comparison/search operation (e.g., the msk, I_msk, d and I_d input signals) may be connected to input gates of transistors that are closer to the comparison circuitry's (i.e., comparison circuitry 302 in FIG. 6) power supply (e.g., labeled ‘Vdd’ in FIG. 6) while input signals that are subject to changing during search/comparison operations (e.g., the I_key and key input signals) may be connected to input gates of transistors that are closer to the match output line (e.g., I_match in FIG. 6). According to certain aspects, FIG. 6 illustrates one such order of input signals to transistors.

According to certain aspects, connecting the transistors closer to the power supply with input signals that do not change during a comparison operation allows the drain nodes of the transistors associated with these signals to remain at a constant voltage. Take, for example, the net labeled “a” of the comparison circuitry 302 in FIG. 6. This net (i.e., net ‘a’) is connected to the drain of a PFET which has its gate tied to the input signal “msk1”. If msk1 is LOW, net “a” will remain at the power supply voltage, Vdd. If net msk1 is HIGH, net “a” may switch between Vdd and Vtp (i.e., the threshold voltage) voltages, but may also remain constant, depending on the state of the other inputs. Thus, according to certain aspects, connecting the inputs to the transistors/stages in the comparison circuitry 302 in the fashion illustrated in FIG. 6 ensures that a minimum amount of nets (e.g., one net: I_match) switch during a comparison operation while allowing a remaining number of nets to remain at a constant voltage. According to certain aspects, minimizing the number of nets that switch during a comparison operation reduces power dissipation. It should be noted, that while FIG. 6 illustrates one particular order for assigning input signals to input gates of transistors, other orders may exist.

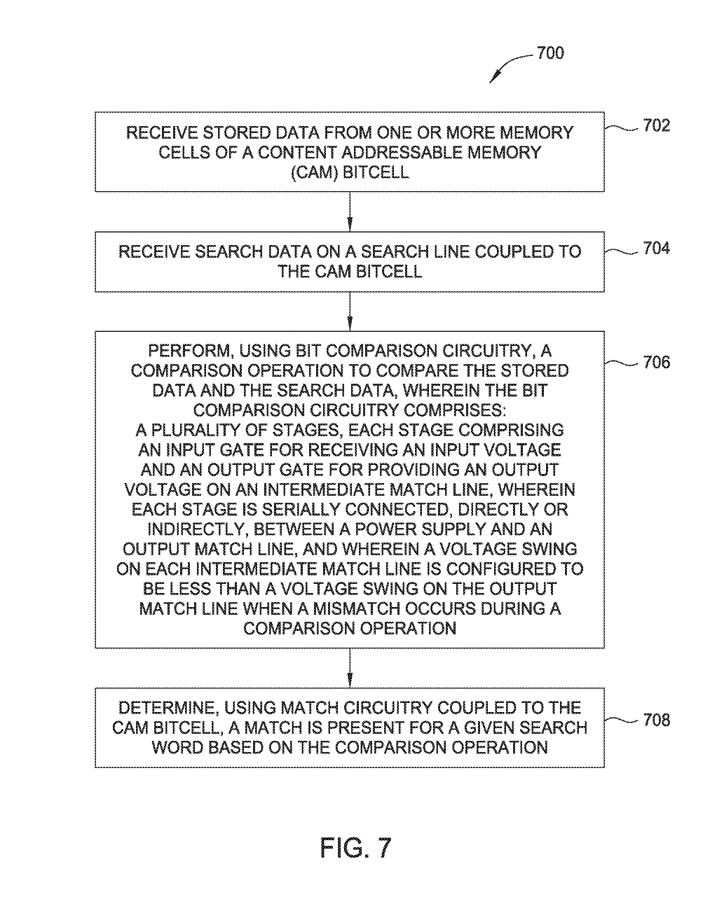

FIG. 7 illustrates example operations 700 for operating a ternary content addressable memory (TCAM) bitcell, in accordance with certain aspects of the present disclosure. According to certain aspects, the TCAM bitcell may comprise comparison circuitry (e.g., caparison circuitry 302 illustrated in FIG. 6) that limits power dissipation during comparison operations.

Operations 700 begin at 702 by receiving stored data from one or more memory cells of the TCAM bitcell. At 704 the TCAM bitcell receives search data on a search line coupled to the TCAM bitcell. At 706, the TCAM bitcell performs, using bit comparison circuitry, a comparison operation to compare the stored data and the search data.

According to certain aspects and as noted above, the bit comparison circuitry (e.g., comparison circuitry 302 illustrated in FIG. 6) may comprise a plurality of stages (e.g., transistors), each stage comprising an input gate for receiving an input voltage (e.g., an input signal) and an output gate for providing an output voltage on an intermediate match line. According to certain aspects and as referred to herein, an intermediate match line may comprise the connections between two or more stages (e.g., the intermediate match line/net labeled ‘a’ in FIG. 6) in the comparison circuitry, not including the output match line (e.g., labeled ‘I_match’ in FIG. 6) which is used to indicate whether there is a match between the stored data and the search data. According to certain aspects, each stage in the comparison circuitry may be serially connected, directly or indirectly, between a power supply (e.g., Vdd and/or Vss) and the output match line. Additionally, according to certain aspects, the comparison circuitry may be configured (e.g., inputs to the plurality of stages may be assigned in a particular order, for example, as described above) such that a voltage swing on each intermediate match line is configured to be less than a voltage swing on the output match line when a mismatch (e.g., when the stored data does not match the search data) occurs during a comparison operation.

At 708, the TCAM bitcell determines, using match circuitry coupled to the TCAM bitcell, a match is present for a given search word based on the comparison operation. According to certain aspects, the match circuitry may comprise, for example, a priority encoder, such as the priority encoder 240 illustrated in FIG. 2, which is configured to determine matches between stored data and search data and output the corresponding addresses in memory.

While aspects of the present disclosure generally relate to ternary content addressable memories (TCAMs), the techniques presented herein may also be applicable to other types of content addressable memories, such as binary content addressable memory (BCAM), which perform exact-match searches using only 0s and 1s (i.e., searches without a “don't care” state).

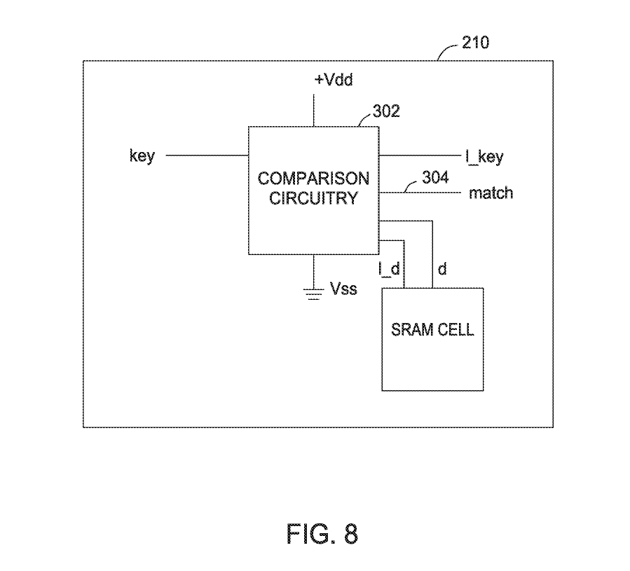

FIG. 8 illustrates and example of a BCAM bitcell 800, according to certain aspects of the present disclosure. In accordance with certain aspects, the TCAM bitcell 210 illustrated in FIG. 2 may comprise the BCAM bitcell 800. As illustrated, the BCAM bitcell 800 may be similar to the TCAM bitcell 210 illustrated in FIG. 3; however, since a BCAM does not use a “don't care” bit, the BCAM bitcell 800 does not include an SRAM cell for mask information and thus the comparison circuitry 302 illustrated in FIG. 8 does not have mask signal inputs.

Additionally, as illustrated, the BCAM bitcell 800 may include comparison circuitry 302 operable to provide a match output signal (e.g., on output match line 304) during a comparison/search operation.

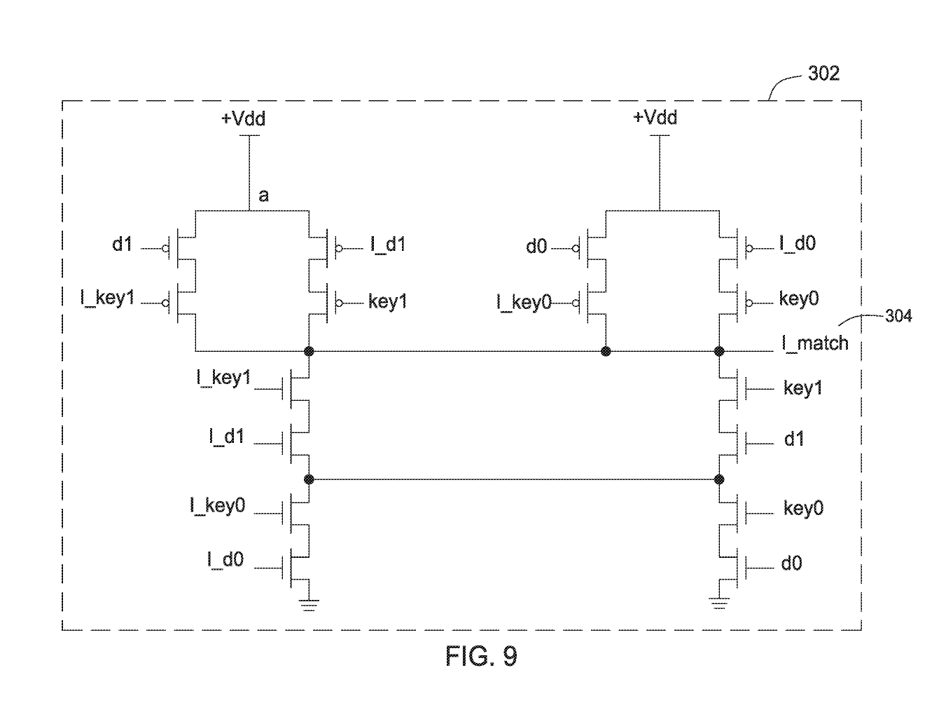

FIG. 9 illustrates example comparison circuitry for a low-power BCAM, according to certain aspects of the present disclosure. According to certain aspects, the comparison circuitry 302 illustrated in FIG. 8 may comprise the comparison circuitry illustrated in FIG. 9.

According to certain aspects, the comparison circuitry illustrated in FIG. 9 may function similar to the comparison circuitry illustrated in FIG. 6. For example, the comparison circuitry 302 illustrated in FIG. 9 may function to reduce the number of intermediate match lines that switch during a comparison operation (e.g., by assigning the input signals to the transistors illustrated FIG. 9 in a particular order), reduce the voltage swing on intermediate output lines, and reduce a switched capacitance. According to certain aspects, one example order for reducing the number of intermediate match lines is illustrated in FIG. 9. While FIG. 9 illustrates one order to reduce the number of intermediate match lines that switch, other orders may exist.

In the preceding, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Aspects of the present disclosure may be a system, a method, and/or a computer program product. The computer program product may include a computer readable storage medium (or media) having computer readable program instructions (e.g., logic) thereon for causing a processor to carry out aspects described herein.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described above with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality and operation of possible implementations of systems, methods and computer program products according to various embodiments. In this regard, each block in the flowchart or block diagrams may represent a module, segment or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-oriented systems that perform the specified functions or acts, or combinations of special purpose hardware and computer instructions.

In view of the foregoing, the scope of the present disclosure is determined by the claims that follow.

We claim:

1. A content addressable memory (CAM) bitcell, comprising:
bit storage comprising one or more memory cells for holding stored data;
bit comparison circuitry operative to compare the stored data and search data, received on a search line coupled to the CAM bitcell, and to provide a match output signal on an output match line, the bit comparison circuitry comprising:
a plurality of stages, each stage comprising an input gate for receiving an input voltage and an output gate for providing an output voltage on an intermediate match line, wherein each stage is serially connected, directly or indirectly, between a power supply and the output match line, and wherein a voltage swing on each intermediate match line is configured to be less than a voltage swing on the output match line when a mismatch occurs during a comparison operation; and
match circuitry coupled to receive the match output signal from the CAM bitcell for determining whether a match is present for a given search word.

2. The CAM bitcell of claim 1, wherein each stage in the plurality of stages is connected in an order based on an input signal to be applied to the input gate of each stage.

3. The CAM bitcell of claim 2, wherein stages whose input voltage does not change during a comparison operation are connected closer to the power supply than stages whose input changes during the comparison operation.

4. The CAM bitcell of claim 2, wherein the order of stages reduces an overall switched capacitance of the CAM.

5. The CAM bitcell of claim 1, wherein the voltage swing on each intermediate match line is between a supply voltage provided by the power supply and a threshold voltage for the stage associated with the intermediate match line, and wherein the voltage swing on the match line is between the supply voltage and ground.

6. The CAM bitcell of claim 1, wherein the CAM bitcell comprises a ternary content addressable memory (TCAM) bitcell.

7. The CAM bitcell of claim 1, wherein the CAM bitcell comprises a binary content addressable memory (BCAM).

8. A method of operating a content addressable memory (CAM) bitcell, comprising:
receiving stored data from one or more memory cells of the CAM bitcell;
receiving search data on a search line coupled to the CAM bitcell;
performing, using bit comparison circuitry, a comparison operation to compare the stored data and the search data, wherein the bit comparison circuitry comprises:
a plurality of stages, each stage comprising an input gate for receiving an input voltage and an output gate for providing an output voltage on an intermediate match line, wherein each stage is serially connected, directly or indirectly, between a power supply and an output match line, and wherein a voltage swing on each intermediate match line is configured to be less than a voltage swing on the output match line when a mismatch occurs during a comparison operation; and
determining, using match circuitry coupled to the CAM bitcell, a match is present for a given search word based on the comparison operation.

9. The method of claim 8, wherein each stage in the plurality of stages is connected in an order based on an input signal to be applied to the input gate of each stage.

10. The method of claim 9, wherein stages whose input voltage does not change during a comparison operation are connected closer to the power supply than stages whose input changes during the comparison operation.

11. The method of claim 9, wherein the order of stages reduces an overall switched capacitance of the CAM.

12. The method of claim 8, wherein the voltage swing on each intermediate match line is between a supply voltage provided by the power supply and a threshold voltage for the stage associated with the intermediate match line, and wherein the voltage swing on the match line is between the supply voltage and ground.

13. The method of claim 8, wherein the CAM bitcell comprises a ternary content addressable memory (TCAM) bitcell.

14. The method of claim 8, wherein the CAM bitcell comprises a binary content addressable memory (BCAM).

15. Logic encoded in one or more tangible media for execution and when executed operable to:
receive stored data from one or more memory cells of a content addressable memory (CAM) bitcell;
receive search data on a search line coupled to the CAM bitcell;
perform, using bit comparison circuitry, a comparison operation to compare the stored data and the search data, wherein the bit comparison circuitry comprises:
a plurality of stages, each stage comprising an input gate for receiving an input voltage and an output gate for providing an output voltage on an intermediate match line, wherein each stage is serially connected, directly or indirectly, between a power supply and the output match line, and wherein a voltage swing on each intermediate match line is configured to be less than a voltage swing on the output match line when a mismatch occurs during a comparison operation; and
determine, using match circuitry coupled to the CAM bitcell, a match is present for a given search word based on the comparison operation.

16. The logic of claim 15, wherein each stage in the plurality of stages is connected in an order based on an input signal to be applied to the input gate of each stage.

17. The logic of claim 16, wherein stages whose input voltage does not change during a comparison operation are connected closer to the power supply than stages whose input changes during the comparison operation.

18. The logic of claim 16, wherein the order of stages reduces an overall switched capacitance of the CAM.

19. The logic of claim 15, wherein the voltage swing on each intermediate match line is between a supply voltage provided by the power supply and a threshold voltage for the stage associated with the intermediate match line, and wherein the voltage swing on the match line is between the supply voltage and ground.

20. The logic of claim 15, wherein the CAM bitcell comprises a ternary content addressable memory (TCAM) bitcell or a binary content addressable memory (BCAM).
